(19) United States
(12) Patent Application Publication
(10) Pub. No.: US 2011/0170243 A1
(43) Pub. Date: Jul. 14, 2011

(54) ADAPTER ELEMENT AND ELECTRONIC DEVICE USING THE SAME

(75) Inventor: Yu-Yuan LIN, Taipei City (TW)

(73) Assignee: COMPAL ELECTRONICS, INC., Taipei City (TW)

(21) Appl. No.: 12/770,679

(22) Filed: Apr. 29, 2010

(30) Foreign Application Priority Data
Jan. 13, 2010 (TW) 99100839

(51) Int. Cl. H05K 5/00

(52) U.S. Cl. 361/679.01

(57) ABSTRACT

Disclosed herein are an adapter element and an electronic device using the same. The adapter element is disposed between a casing and a keyboard module of the electronic device. The adapter element at least includes a first join structure and a second join structure. The keyboard is joined with one of the two join structures.

### RELATED APPLICATIONS

This application claims priority to Taiwan Application Serial Number 99100839, filed Jan. 13, 2010, which is herein incorporated by reference.

### BACKGROUND

1. Technical Field

The present invention relates to a mechanical structure and a device using the structure. More particularly, the present invention relates to an adapter element for keyboard modules and an electronic device using the same.

2. Description of Related Art

A keyboard module is the most basic and the most important input module of an electronic device such as a notebook computer.

In order to meet the requirements of different product models from various product lines, the casing of an electronic device is usually designed to match with one specific keyboard module. Therefore, when the manufacturer wants to assemble the casing with a different keyboard module, the mechanical design of the casing needs to be modified. However, the modification of the casing requires massive time and labor cost. Particularly when it comes to alter the specification of molding, the manufacturing cost is increased enormously.

### SUMMARY

An adapter element and an electronic device using the same are provided to solve the problems of modifying the casing with different keyboard modules and increasing the manufacturing cost.

According to one aspect of the invention, an electronic device is provided. The electronic device includes a casing, a keyboard module and an adapter element. The keyboard module is disposed on the casing and the adapter element is disposed between the casing and the keyboard module. The adapter element includes a first join structure and a second join structure, the keyboard is connected to one of the two join structures.

According to one embodiment of the invention, the first join structure is a hook for hooking with a fastener of the keyboard module. The second join structure is an insert hole for a protruded column of the keyboard module to plug in.

According to one embodiment of the invention, the first join structure is a first hook or a first insert hole having a first arrangement, and the second join structure is a second hook or a second insert hole having a second arrangement. The two arrangements are different from each other.

According to one embodiment of the invention, the adapter element further includes a third join structure. The keyboard module is selectively joined with the first join structure, the second join structure or the third join structure.

According to one embodiment of the invention, the three join structures are the same join structure. The three join structures have different arrangements.

According to another aspect of the invention, an adapter element disposed between a keyboard and a casing is provided. The adapter element includes a main body, a first join structure and a second join structure. The two join structures are disposed on the main body. The keyboard module is joined with one of the two join structures.

In the foregoing adapter element and electronic device using the same of the embodiments of the invention, the casing is applicable to connect to different keyboard modules through the adapter element. The modification of the casing for different keyboard modules is not required, thus lowering the manufacturing cost.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A is an exploded diagram of an electronic device according to one embodiment of the invention;

FIG. 1B is a back view of the first keyboard module in FIG. 1A;

FIG. 2A is an exploded diagram of an electronic device according to another embodiment of the invention;

FIG. 2B is a back view of the second keyboard module in FIG. 2A; and

FIG. 3 is a three-dimensional diagram of an adapter element according to yet another embodiment of the invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

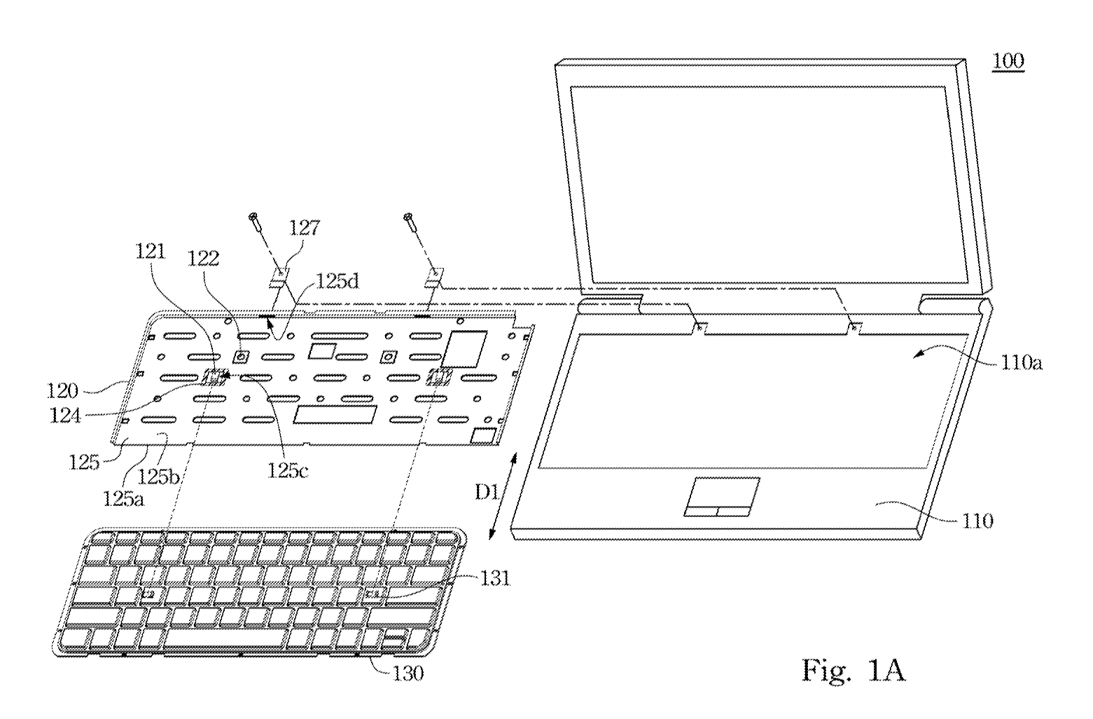

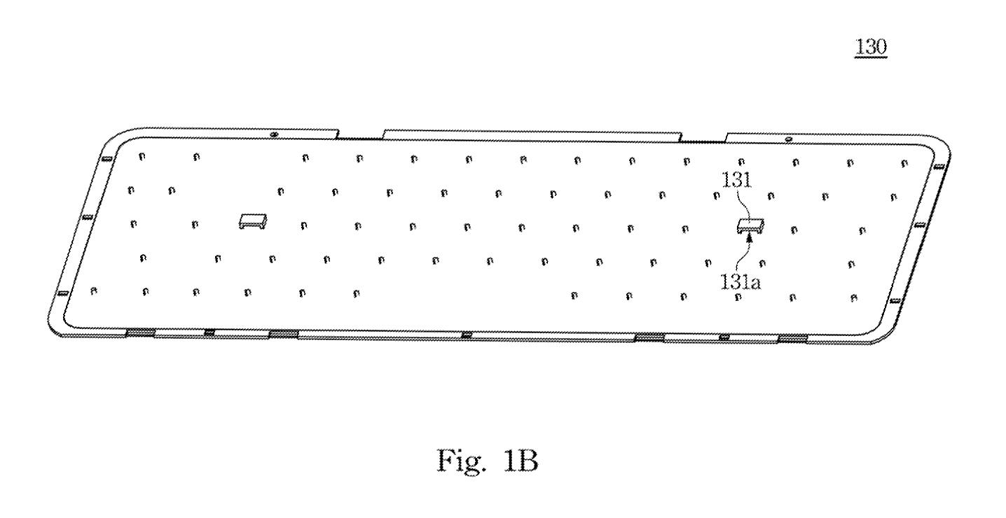

FIG. 1A is an exploded diagram of an electronic device according to one embodiment of the invention. The electronic device 100 includes a casing 110, a first keyboard module 130 and an adapter element 120. The adapter element 120 is disposed between the casing 110 and the first keyboard module 130, so as to join the first keyboard module 130 onto the casing 110. Exemplarily, the electronic device 100 is a notebook computer, an electronic dictionary or any other electronic devices requiring a keyboard module.

In the below description, the adapter element 120 is exemplified by a flat plate or a frame; however, the technology of the invention is not limited thereto. For example, the adapter element 120 and the casing 110 can be formed in one piece.

More specifically, the adapter element 120 includes a main body 125, a first join structure 121 and a second join structure 122. The two join structures 121 and 122 are disposed on the main body 125. The main body 125 has a first disposition surface 125a and an opposite second disposition surface 125b. The main body 125 is disposed onto the casing 110 through the first disposition surface 125a. The first keyboard module 130 is joined with one of the two join structures 121 and 122, so as to be disposed onto the second disposition surface 125b and thereby further connected to the casing 110. In the present embodiment, the first join structure 121 and the second join structure 122 are provided with different mechanical designs to match with different keyboard modules.

The first keyboard module 130 is disposed on the second disposition surface 125b by joining with the first join structure 121 in the present embodiment. The first join structure 121 is exemplified by a hook, and the first keyboard module 130 correspondingly includes a fastener 131, as shown in FIG. 1B. FIG. 1B is a back view of the first keyboard module in FIG. 1A. The fastener 131 is fastened by the hook, so as to fix the first keyboard module 130 onto the adapter element 120. Furthermore, the first join structure 121 includes a hook portion 125c extending along a direction D1 that is parallel to the second disposition surface 125b, i.e. the flat plate direction of the main body 125. The fastener 131 is protruded from the surface of the first keyboard module 130 and constitutes a through hole 131a with the surface. The extending direction of the through hole 131 is generally parallel to the plate of the first keyboard module 130. While connecting the first keyboard module 130, the first join structure 121 (the hook) goes through the through hole 131a in the direction D1 and then locks with the fastener 131 to fix the first keyboard module 130.

In addition, the adapter element 120 further includes an adhesion layer 124 at least disposed on a part of the second disposition surface 125b that is ambient to the first join structure 121. As the first keyboard module 130 connected to the second disposition surface 125b through the first join structure 121, the first keyboard module 130 is further adhered to the adapter element 120 via the adhesion layer 124, so as to increase the stability of the first keyboard module 130.

The adapter element 120 includes a fixing plate 127 and the casing 110 has a receiving recess 110a. The adapter element 120 is fixed to the casing 110 through the fixing plate 127. The adapter element 120 is received in the receiving recess 110a with the first disposition surface 125a facing the receiving recess 110a. Exemplarily, the area of the bottom surface of the receiving recess 110a is approximately the same as the area of the first disposition surface 125a. The bottom surface of the receiving recess 110a evenly contacts with the first disposition surface 125a. Further, the main body 125 of the adapter element 120 includes an opening 125d. One end of the fixing plate 127 is inserted into the opening 125d and locks with the main body 125. Another end of the fixing plate 127 is connected to the casing 110. Practically, the fixing plate 127 can be exemplified by connecting to the casing 110 through a screw. As a result, the adapter element 120 is connected to the casing 110 through the fixing plate 127.

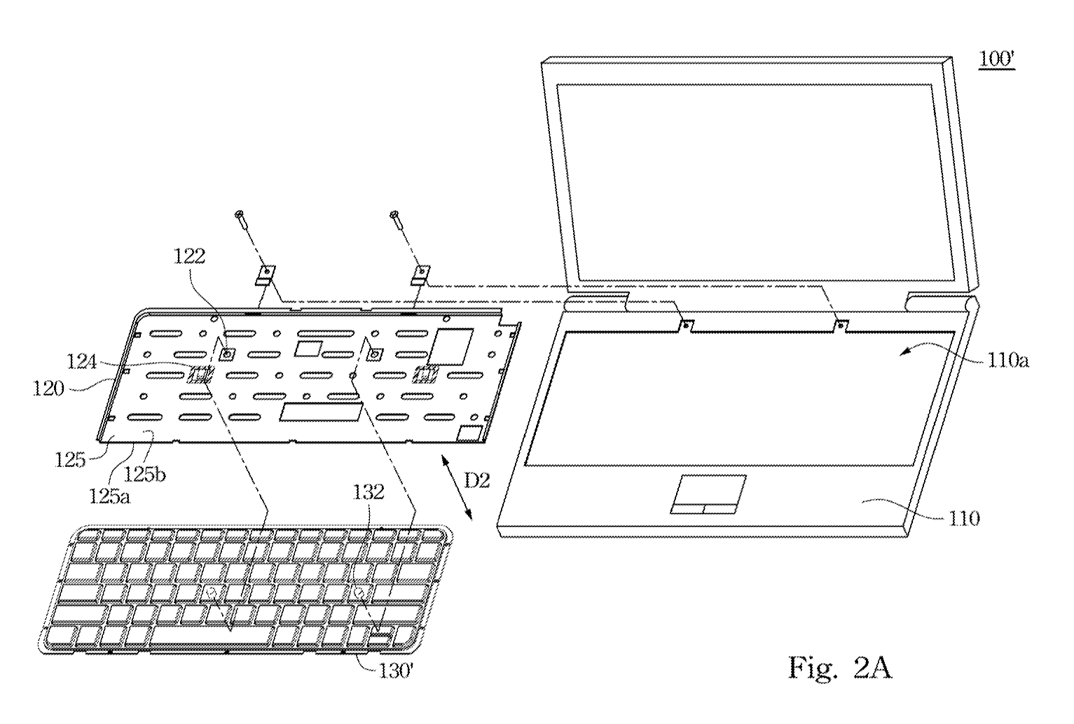

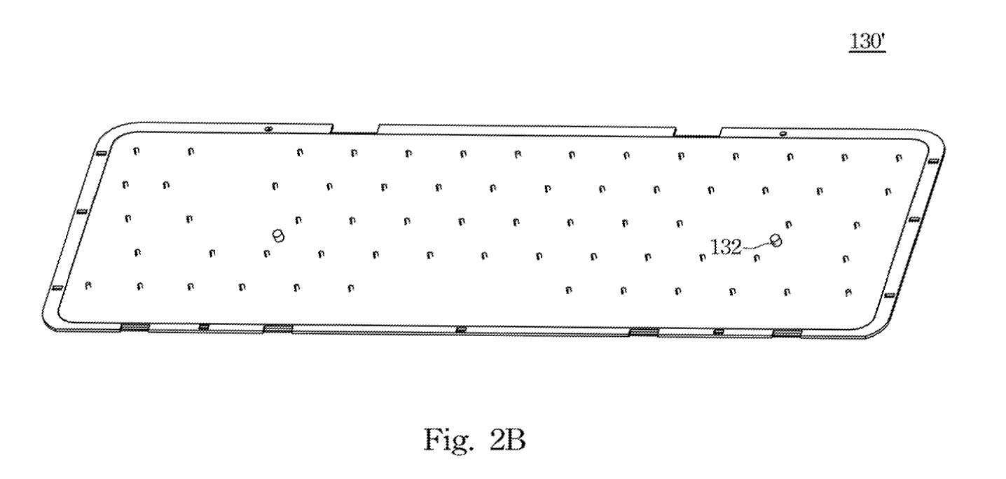

As shown in FIG. 2A, the adapter element 120 can be used to join with another keyboard module 130′. FIG. 2A is an exploded diagram of an electronic device according to another embodiment of the invention. The electronic device 100′ includes the casing 110, the adapter element 120 and a second keyboard module 130′. The second keyboard module 130′ is different from the previously-mentioned first keyboard module 130. The second keyboard module 130′ is disposed on the second disposition surface 125b by joining with the second join structure 122.

In the present embodiment, the second join structure 122 is an insert hole and the second keyboard module 130′ includes a protruded column 132, as shown in FIG. 2B. FIG. 2B is a back view of the second keyboard module in FIG. 2A. The protruded column 132 is disposed on the surface of the second keyboard module 130′ and is generally parallel to the upright direction of the plate of the second keyboard module 130′. The second keyboard module 130′ is disposed on the adapter element 120 by plugging the protruded column 132 into the insert hole. The cross-sectional area of the insert hole on the second disposition surface 125b is approximately the same as that of the protruded column 132. Therefore, the protruded column 132 is firmly wedged with the insert hole once the protruded column 132 is plugged into the insert hole in a direction D2 perpendicular to the second disposition surface 125b.

In the above description, the adhesion layer 124 is at least disposed on a part of the second disposition surface 125b that is ambient to the first join structure 121, as shown in FIG. 1A. However, the disposition of the adhesion layer 124 is not limited thereto. In the present embodiment with referring to FIG. 2A, the adhesion layer 124 is at least disposed on a part of the second disposition surface 125b that is ambient to the second join structure 122. As the second keyboard module 130′ connected to the second disposition surface 125b through the second join structure 122, the second keyboard module 130′ is further adhered to the adapter element 120 via the adhesion layer 124. Moreover, in another embodiment, the adhesion layer 124 fully covers the second disposition surface 125b, such that both the first and the second keyboard module 130 and 130′ can be adhered onto the adapter element 120 through the adhesion layer 124.

In the above-described adapter element 120, the first keyboard module 130 and the second keyboard module 130′ are selectively disposed onto the second disposition surface 125b through the first join structure 121 or the second join structure 122. The first join structure 121 has a first arrangement on the main body 125, and the second join structure 122 has a second arrangement on the main body 125. The two arrangements are different, which makes the first join structure 121 and the second join structure 122 situate in different locations on the main body 125.

In another embodiment, the first join structure 121 and the second join structure 122 are the same join structures, and the first keyboard module 130 and the second keyboard module 130′ include the same corresponding fastening structures. For example, the first join structure 121 is a first hook and the first keyboard module 130 includes a first fastener for fastening with the first hook. The second join structure 122 is a second hook and the second keyboard module 130′ includes a second fastener for fastening with the second hook. In another example, the first join structure 121 is a first insert hole and the first keyboard module 130 includes a first protruded column for plugging into the first insert hole. The second join structure 122 is a second insert hole and the second keyboard module 130′ includes a second protruded column for plugging into the second insert hole.

Although the adapter element 120 is exemplified by two join structures (the first join structure 121 and the second join structure 122), the join structures of the adapter element 120 is not limited to two categories. The adapter element 120 can include more than three categories of join structures, so as to adapt to more keyboard modules. Furthermore, the numbers of the first join structure 121 and the second join structure 122 are not limited to that illustrated in FIG. 1A and FIG. 2A. Practically, the number of the first join structure 121 is the same as the number of the fastener 131 on the first keyboard module 130. The number of the second join structure 122 is the same as the number of the protruded column 132 on the second keyboard module 130′.

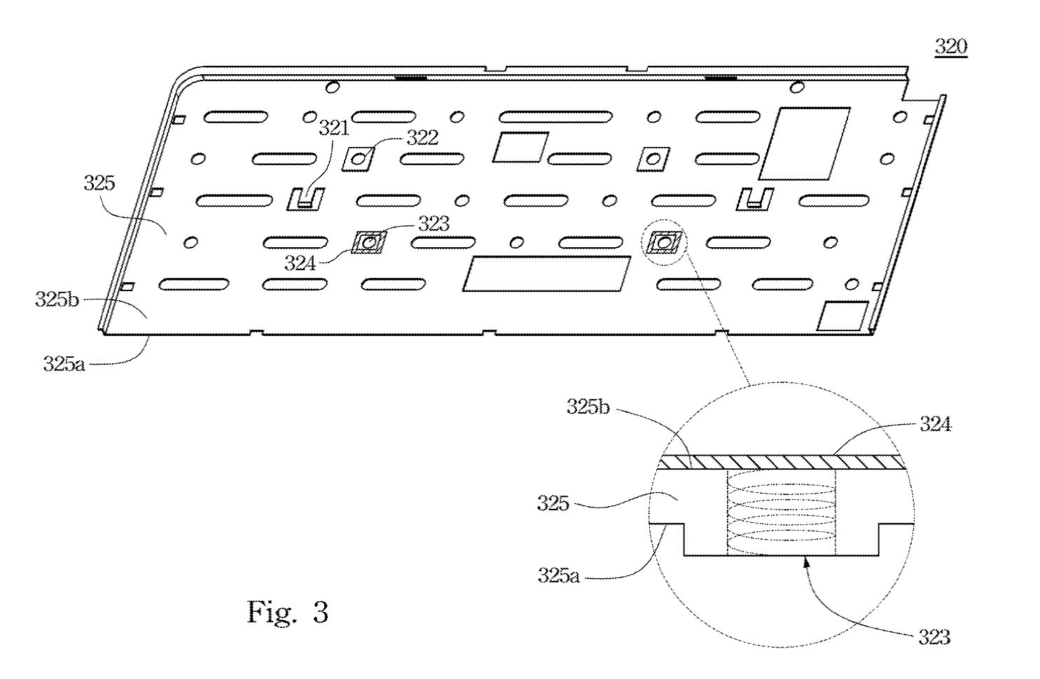

In another embodiment of the invention, an adapter element 320 further includes a third join structure 323, as shown in FIG. 3. FIG. 3 is a three-dimensional diagram of an adapter element according to yet another embodiment of the invention. The adapter element 320 includes a main body 325, a first join structure 321, a second join structure 322 and the third join structure 323. The main body 325 has a first disposition surface 325a and an opposite second disposition surface 325b. The main body 325 is disposed on a casing of an electronic device (not shown in FIG. 3) with the first disposition 325a facing the casing. The three join structures 321, 322 and 323 are disposed on the main body 325 for selectively joining with a first keyboard module, a second keyboard module and a third keyboard module. Similarly, in the present embodiment, the first join structure 321 is one or more hooks and the second join structure 322 is one or more insert holes. Their designs and dispositions will not be repeated here. The third join structure 323 is exemplified by a screw hole having screw threads therein. The third keyboard module includes a screw to lock with the screw hole. The adapter element 320 further includes an adhesion layer 324 at least disposed on a part of the second disposition surface 325b that is ambient to the third join structure 323 to adhere the third keyboard module.

The first keyboard module, the second keyboard module and the third keyboard module are selectively disposed onto the second disposition surface 325b of the adapter element 320 through the first join structure 321, the second join structure 322 and the third join structure 323 respectively. Therefore the three keyboard modules can be selectively connected to the casing of the electronic device. The first join structure 321 has a first disposition, the second join structure 322 has a second disposition and the third join structure 323 has a third disposition. The three dispositions are different from each other, which makes the three join structures 321,322 and 323 situate in different locations on the main body 325.

In another embodiment, the three join structures 321, 322 and 323 are the same join structures, and the three keyboard modules include the same corresponding fastening structures. For example, the three join structures 321, 322 and 323 are all hooks, and the three keyboard modules include corresponding fasteners. In another example, the three join structures 321, 322 and 323 are all insert holes, and the three keyboard modules include corresponding protruded columns.

In the above-described adapter element and the electronic device using the same of the embodiments of the invention, the adapter element includes two or more than two join structures to join with different keyboard modules. The keyboard module of the electronic device is connected to the casing by joining with one of the join structures, and the modification of the casing for different keyboard modules is not required. Therefore the manufacturing process is simplified and the cost is saved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electronic device, comprising:
a casing;
a keyboard module disposed on the casing; and
an adapter element disposed between the casing and the keyboard module and comprising a first join structure and a second join structure, wherein the keyboard module is joined with one of the two join structures.

2. The electronic device of claim 1, wherein the first join structure is a hook for hooking with a fastener of the keyboard module.

3. The electronic device of claim 2, wherein the second join structure is an insert hole for a protruded column of the keyboard module to plug in.

4. The electronic device of claim 1, wherein the first join structure is a first hook having a first arrangement and the second join structure is a second hook having a second arrangement, and the two arrangements are different from each other.

5. The electronic device of claim 1, wherein the first join structure is a first insert hole having a first arrangement and the second join structure is a second insert hole having a second arrangement, and the two arrangements are different from each other.

6. The electronic device of claim 1, further comprising:
an adhesion layer at least disposed on the adapter element to adhere the keyboard module.

7. The electronic device of claim 1, wherein the adapter element further comprises a third join structure, wherein the keyboard module is selectively joined with the first join structure, the second join structure or the third join structure.

8. The electronic device of claim 7, wherein the first join structure, the second join structure and the third join structure are the same join structure, and the first join structure, the second join structure and the third join structure respectively have a first arrangement, a second arrangement and a third arrangement that are different from each other.

9. The electronic device of claim 1, wherein the adapter element further comprises an opening and a fixing plate, and the fixing plate has one end for fastening with the opening and another end for connecting to the casing.

10. The electronic device of claim 1, wherein the adapter element and the casing are formed in one piece.

11. An adapter element disposed between a keyboard module and a casing and comprising:
a main body;
a first join structure disposed on the main body; and
a second join structure disposed on the main body, wherein the keyboard module is joined with one of the two join structures.

12. The adapter element of claim 11, wherein the adapter element and the casing are formed in one piece.
